(19) United States
(12) Patent Application Publication
(10) Pub. No.: US 2026/0369513 A1
(43) Pub. Date: Nov. 19, 2026

(54) Triode Electrostatic Optics for Angled Ribbon Ion Beam Extraction

(71) Applicant: Applied Materials, Inc., Santa Clara, CA (US)

(72) Inventors: Costel Biloiu, Rockport, MA (US); Frank Sinclair, Hartland, ME (US); Christopher W. Campbell, Newbury, MA (US)

(21) Appl. No.: 19/209,571

(22) Filed: May 15, 2025

(51) Int. Cl. H01J 37/08; H01J 37/12; H01J 37/20

(52) U.S. Cl. CPC H01J 37/08; H01J 37/12; H01J 37/20; H01J 2237/20235

(57) ABSTRACT

An ion source having a plasma chamber with multiple extraction apertures is disclosed. The extraction optics of the ion source comprise a triode configuration, wherein one of the plates is the extraction plate, which is electrically connected to the walls of the plasma chamber or biased independently in the case where the walls of the plasma chamber are made of dielectric material. The other two plates are biased at different voltages than the extraction plate. Each of the three plates in the extraction optics has two elongated apertures to allow for the extraction of two symmetric angled ribbon ion beams. The use of a triode configuration reduces the beam angular spread while allowing higher beam current, allowing more precise processing of the workpiece at higher processing throughput.

### FIELD

Embodiments of the present disclosure relate to an ion source with multiple extraction apertures and triode extraction optics.

### BACKGROUND

The fabrication of semiconductor devices involves a plurality of discrete and complex processes. Accordingly, many prior art designs were optimized for ion implantation. Recently, in addition to ion implantation, there has been a transition to other processes, such as deposition, etching and other material modification processes, such as amorphization.

Angled processes refer to those in which the beam strikes the substrate at a non-zero angle. For consistency, an angle of 0° is defined as one in which the beam strikes the substrate at an angle perpendicular to the surface of the substrate. Angled beams have many applications. For example, they may be used to implant a sidewall of a fin structure or a trench. Angled beams may also be used for etching processes, deposition processes and other applications.

In some systems, an ion source directs an ion beam toward the workpiece at a non-zero angle. However, in some applications, it is beneficial to perform symmetric processing of the workpiece. For example, it may be beneficial to treat a 3D feature on both sides with an ion beam. Depending on the aspect ratio of the trench, it is possible that etched material removed from the trench wall bombarded by the ion beam to redeposit on the opposite wall. Currently, the removal of the redeposited material is done by scanning the workpiece through the angled ion beam, and after the entire workpiece has been processed, the workpiece is rotated 180° and then scanned again.

This process is effective but may be time consuming as it uses two scanning passes of the workpiece with a 180° rotation between these two passes.

Additionally, there is value in creating these angled ion beams with a small distribution of angles and high beam current.

Therefore, it would be advantageous if there was a system that had multiple extraction apertures, so that both surfaces of a 3D feature may be processed during a single scan. Further, it would be beneficial if this ion source was able to create these symmetric angled ribbon ion beams with a small distribution of angles and high beam current.

### SUMMARY

An ion source having a plasma chamber with multiple extraction apertures is disclosed. The extraction optics of the ion source comprise a triode configuration, wherein one of the plates is the extraction plate, which is electrically connected to the walls of the plasma chamber or biased independently in the case where the walls of the plasma chamber are made of dielectric material. The other two plates are biased at different voltages than the extraction plate. Each of the three plates in the extraction optics has two elongated apertures to allow for the extraction of two symmetric angled ribbon ion beams. The use of a triode configuration reduces the beam angular spread while allowing higher beam current, allowing more precise processing of the workpiece at higher processing throughput.

According to one embodiment, an ion source is disclosed. The ion source comprises a plasma housing defining a plasma chamber; a plasma generator to create a plasma within the plasma chamber; and triode extraction optics, comprising: an extraction plate physically coupled to the plasma housing; a suppression plate; and a ground plate; wherein the suppression plate is disposed between the extraction plate and the ground plate and each plate comprises two or more slits to allow for simultaneous extraction of multiple ion beams at different extraction angles. In some embodiments, the extraction plate comprises a concave region such that a center of the concave region in a height direction extends into the plasma chamber more than distal ends of the extraction plate. In certain embodiments, the concave region includes two slits on opposite sides of the center of the concave region. In certain embodiments, two ion beams extracted through the two slits are symmetric about a line normal to a workpiece and passing through the center of the concave region. In certain embodiments, the extraction plate comprises two concave regions, and the suppression plate and the ground plate each have four slits, allowing for simultaneous extraction of four ion beams. In certain embodiments, the extraction plate comprises three concave regions, and the suppression plate and the ground plate each have six slits, allowing for simultaneous extraction of six ion beams. In certain embodiments, the extraction plate is arc-shaped. In certain embodiments, the suppression plate and the ground plate each comprise a concave shape. In certain embodiments, the suppression plate is arc-shaped or box shaped. In certain embodiments, the ground plate is arc-shaped or box shaped. In some embodiments, a difference in voltage between the extraction plate and the ground plate defines an extraction voltage, and a voltage applied to the suppression plate is more negative than a voltage applied to the ground plate. In some embodiments, a separation between the suppression plate and the extraction plate is smallest at the two or more slits of the suppression plate.

According to another embodiment, a workpiece processing system is disclosed. The workpiece processing system comprises an ion source, comprising: a plasma housing defining a plasma chamber; a plasma generator to create a plasma within the plasma chamber; and triode extraction optics, comprising: an extraction plate physically coupled to the plasma housing; a suppression plate; and a ground plate; wherein the suppression plate is disposed between the extraction plate and the ground plate, wherein the extraction plate comprises one or more concave regions, wherein each concave region includes two extraction slits on opposite sides of a center of the concave region in a height direction, and the suppression plate and the ground plate each comprises two or more slits to allow for simultaneous extraction of multiple ion beams at different extraction angles; and a workpiece holder configured to hold a workpiece to be processed by the multiple ion beams. In some embodiments, the workpiece holder moves in the height direction relative to the plasma housing. In some embodiments, a voltage applied to the workpiece holder is a same voltage as a voltage applied to the ground plate such that there is no electrical field between the ground plate and the workpiece holder. In some embodiments, two ion beams are extracted from the two extraction slits in each concave region, and the two ion beams are directed toward the workpiece holder at extraction angles between 10° and 75° and −10° and −75°, respectively. In certain embodiments, the two ion beams are symmetric about a center line of the concave region in a height direction. In some embodiments, the extraction plate comprises two concave regions arranged in the height direction, allowing for simultaneous extraction of four ion beams. In some embodiments, the extraction plate comprises three concave regions arranged in the height direction, allowing for simultaneous extraction of six ion beams. In some embodiments, an angular spread of each of the multiple ion beams is ±5° or less.

### BRIEF DESCRIPTION OF THE FIGURES

For a better understanding of the present disclosure, reference is made to the accompanying drawings, which are incorporated herein by reference and in which:

FIG. 1 is a block diagram of an ion source having two extraction apertures and triode extraction optics according to one embodiment;

FIG. 2 is a side view of the triode configuration of FIG. 1;

FIG. 3 is a cross section of the triode configuration of FIG. 1;

FIG. 4 is an exploded view of the triode configuration of FIG. 1;

FIG. 5 is the ion beam emissivity curve for the ion source of FIG. 1;

FIG. 6 is the ion angular distribution at the workpiece location for the ion source of FIG. 1;

FIG. 7 shows a simulation of the amount of sputtered material that enters the plasma chamber;

FIG. 8 is a cross section of the triode configuration according to another embodiment;

FIG. 9 is the emissivity curve of the beam for the ion source of FIG. 8;

FIG. 10 is the ion angular distribution for the ion source of FIG. 8; and

FIGS. 11A-11B depict a dual triode configuration and a triple triode configuration, respectively.

### DETAILED DESCRIPTION

As described above, angled semiconductor processes, such as angled implant, deposition and etch processes are becoming increasingly common in the semiconductor industry. Therefore, a system that allows 3D features of a workpiece to be processed on both sides during a single scanning pass, while maintaining small beam angular spread and high beam current would be very beneficial. The workpiece may be a silicon wafer, a polysilicon wafer, a silicon carbide wafer, a GaN or GaAs wafer, or another type of substrate.

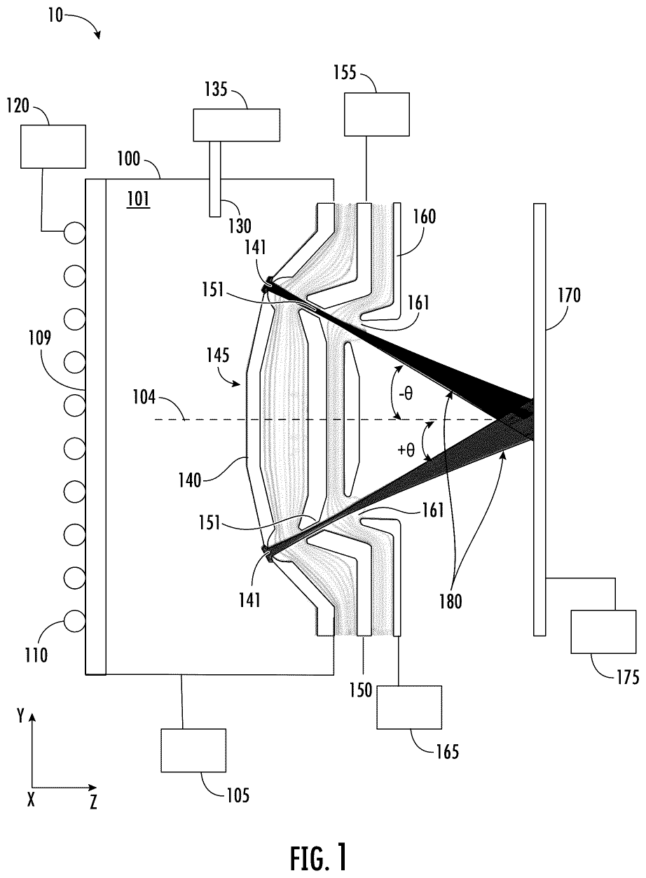

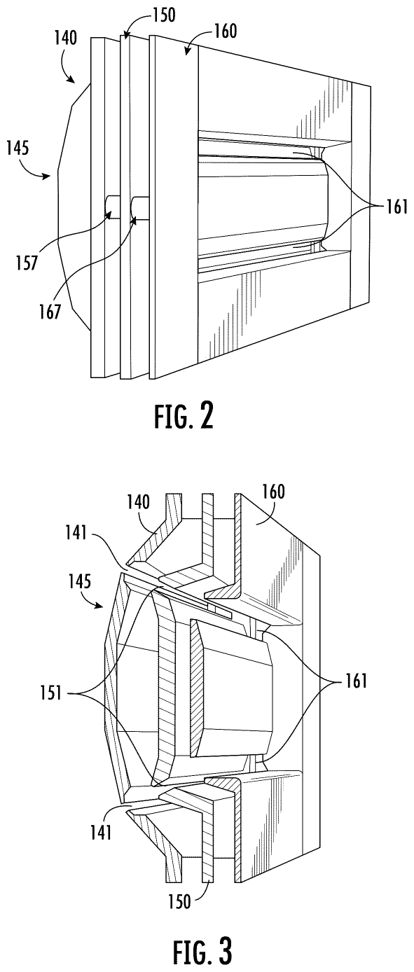

FIG. 1 shows a cross-sectional view of an ion source 10 having two extraction apertures which allows for the extraction of two angled ribbon ion beams 180 according to one embodiment. In this figure, the vertical direction is defined as the Y or height direction, the direction into the page is defined as the X or width direction, and the horizontal direction is defined as the Z direction or the direction of travel for the ion beams. FIGS. 2-4 show a perspective view, a cross-section and an exploded view of the ion extraction optics of FIG. 1, respectively.

The ion source 10 includes a plasma housing 100, which defines a plasma chamber 101. In this embodiment, an RF antenna 110 is disposed outside the plasma chamber 101. The RF antenna 110 is constructed of a conductive material, such as copper and may be cooled. This RF antenna 110 may be disposed proximate to a dielectric window 109 to allow electromagnetic energy radiated from the RF antenna 110 to be inductively coupled to the rarefied gas in the plasma chamber 101. The RF antenna 110 may be powered using an RF power supply 120, which supplies RF voltage to the RF antenna 110 through a matching network (not shown). This RF antenna 110 serves as a plasma generator. Note that other embodiments are also possible. For example, the antenna may be disposed inside the plasma chamber and may be protected by an insulating cover. This insulating cover may be alumina, porcelain or quartz. Note that the disclosure is not limited to this plasma generator. For example, in other embodiments, the plasma generator may include a cathode disposed within the plasma chamber 101, a filament disposed within the plasma chamber 101, or another plasma generator.

A gas inlet 130, which is in communication with a gas source 135, is used to introduce a gas species or a mixture of gas species into the plasma chamber 101.

The plasma housing 100 comprises a plurality of walls, which are typically electrically conductive and may be made of a metal, such as aluminum, tungsten or graphite but also may be electrically non-conductive and made of dielectric materials such as alumina, aluminum nitride and/or quartz. The plurality of walls may form four sides of a rectangular prism. The fifth side, which is the wall adjacent to RF antenna 110 is the dielectric window 109. It is mandatory for this window to be made of dielectric material to couple the RF power from the RF antenna 110 to the plasma. In some embodiments (in the case of electrically conductive walls), the plasma housing 100 may be electrically biased using an extraction power supply 105. The difference in voltage between the plasma housing 100 and the workpiece holder 170 is referred to as the extraction voltage and, in order to extract positive ions, should be positive. The sixth side of the plasma housing 100 comprises an extraction plate 140, which is typically electrically and physically connected to the plasma housing 100. The extraction plate 140 may be made of electrically conductive material, such as aluminum, tungsten, titanium, molybdenum, or graphite. In the case where the walls of the plasma housing 100 are made of dielectric material, then the extraction plate 140 may be electrically biased by the extraction power supply 105. In this case, the difference in voltage between the extraction plate 140 and the workpiece holder 170 is referred to as the extraction voltage. The extraction plate 140 may be a single component. When viewed in the Y-Z plane (parallel to the page), the extraction plate 140 has a region with a concave shape, such that the center of the concave region 145 in the extraction plate 140 (as measured in the height direction) extends further into the interior of the plasma chamber 101 than the distal ends of the extraction plate 140. Further, the extraction plate 140 may include two or more extraction slits 141, which are elongated in the X direction. These extraction slits 141 are much larger in the width direction than in the height direction. In some embodiments, the extraction slits 141 may have a height of 3-10 mm and a width of 350-400 mm. This may allow the simultaneous extraction of two ribbon ion beams 180 having different incidence angles with respect to the normal on the workpiece holder 170.

These extraction slits 141 may be arranged symmetrically about a center line 104 that passes through the center of the concave region 145 of the extraction plate 140 in the height direction. For example, as shown in FIG. 1, the extraction slits 141 may be arranged to create symmetric extraction angles of +θ° and −θ° relative to center line 104 (which is normal to the workpiece holder). Note that the concave shape of the extraction plate 140 may be created using a curved plate, a curvilinear plate, or a plate comprising a plurality of planar segments connected to each other to form an arc-like shape. In one specific embodiment where the extraction plate 140 comprises a plurality of planar segments, the elongated extraction slits may each be located at the connection point of two planar segments. Thus, each concave region 145 is configured to allow the extraction of two ribbon ion beams.

Located on the exterior of the extraction plate 140, which is further from the plasma chamber 101, is a suppression plate 150. The suppression plate 150 may be made of the same material as the extraction plate 140 or may be made of a different conductive material. The suppression plate 150 may be a single component having two or more suppression slits 151. Like the extraction plate, the suppression plate 150 may have a concave shape wherein the center of the suppression plate 150 when measured in the height direction is closer to the center of the plasma chamber 101 than the distal ends. The suppression plate 150 comprises two suppression slits 151, which are centrally aligned and parallel to the extraction slits 141. These suppression slits 151 may be elongated so as to allow the extraction of a ribbon ion beam. In some embodiments, the number of suppression slits 151 is equal to the number of extraction slits 141.

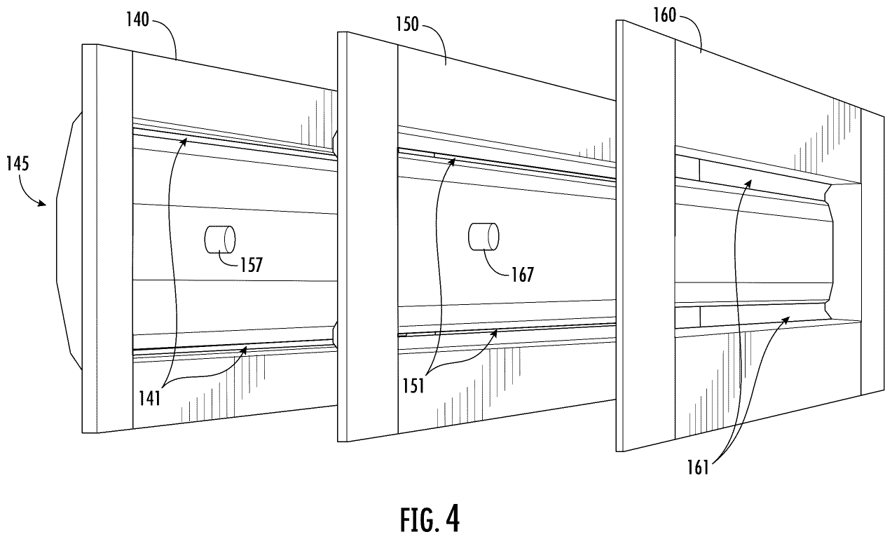

The suppression plate 150 is electrically biased using suppression plate power supply 155. For positive ion extraction, the voltage applied by the suppression plate power supply 155 is negative. Insulators 157 (see FIGS. 2 and 4) are used to maintain physical separation and alignment between the extraction plate 140 and the suppression plate 150.

The suppression plate 150 may be concave, such that the center of the suppression plate as measured in the height direction is closer to the plasma chamber 101 than the distal ends of the suppression plate 150. Like the extraction plate 140, the concave shape of the suppression plate 150 may be created using a curved plate, a curvilinear plate, or a plate comprising a plurality of planar segments connected to each other to form an arc-like or box shape. In certain embodiments, the separation gap between the suppression plate 150 and the extraction plate 140 is smallest at the suppression slits 151. Further, in embodiments where the suppression plate 150 is box shaped, the suppression slits 151 may be disposed in the corners.

A ground plate 160 is disposed on the exterior side of the suppression plate 150, away from the extraction plate 140. The ground plate 160 may be made of the same material as the extraction plate 140 or may be made of a different electrically conductive material. The ground plate 160 may be a single component having two or more ground slits 161. For positive ion extraction, the ground plate 160 is biased at the same voltage as the workpiece holder 170. In some embodiments, this voltage may be electrical ground. Thus, a usual biasing scheme is as follows: the extraction plate 140 is biased at positive voltage (equal to the desired ion energy), the suppression plate 150 is biased at negative voltage, and the ground plate 160 and workpiece holder 170 at ground. In other embodiments, a different biasing scheme can be used, which is as follows: the extraction plate 140 is biased at zero voltage (ground), suppression plate 150 is biased at a negative voltage, and the ground plate 160 and the workpiece holder 170 are biased at a smaller negative voltage equal to the desired ion energy. This voltage may be supplied by an additional ground plate power supply 165.

Insulators 167 (see FIGS. 2 and 4) are used to maintain physical separation and alignment between the ground plate 160 and the suppression plate 150.

The ground plate 160 may be concave, such that the center of the ground plate as measured in the height direction is closer to the plasma chamber 101 than the distal ends of the ground plate 160. Further, like the other plates, the concave shape of the ground plate 160 may be created using a curved plate, a curvilinear plate, or a plate comprising a plurality of planar segments connected to each other to form an arc-like or box shape. The ground plate 160 also comprises two ground slits 161, which may be elongated slits. Further, in embodiments where the ground plate 160 is box shaped, the ground slits 161 may be disposed in the corners. The number of ground slits 161 may be the same as the number of suppression slits 151 and the number of extraction slits 141. Further, the ground slits 161 are centrally aligned and parallel to the extraction slits 141 and the suppression slits 151 such that there is a straight line of sight from the interior of the plasma chamber 101 through the extraction slits 141, the suppression slits 151 and the ground slits 161. The size of the suppression slits 151 and the ground slits 161 may be the same as the size of the extraction slits 141 but generally, the suppression slits are slightly narrower than the extraction slits and ground slits.

The use of three plates, biased at different electrostatic potentials, as shown in FIGS. 1-4, is referred to as a triode ion extraction configuration.

While FIG. 1 shows one embodiment, it is understood that the exact shape of the three plates, their spatial separation, and size and position of their respective slits depend on the desired ion angular distribution.

Located exterior to the ground plate 160 is the workpiece holder 170. The workpiece holder 170 may be an electrostatic chuck or another type of holder. The workpiece holder 170 may be biased at the same voltage as the ground plate 160 such that there are no electrical fields in the space between the workpiece holder 170 and the ion source 10. Further, the workpiece holder 170 may be driven by a motion stage 175 so as to move in the height direction relative to the ion source 10. Further, the workpiece holder 170 may be capable of rotation about an axis parallel to the Z direction, an axis parallel to the X direction and/or an axis parallel to the Y direction.

In operation, one or more gas species are introduced into the plasma chamber 101 via the gas inlet 130. Electrical power is supplied by the RF power supply 120 to the RF antenna 110, which couples the energy into the plasma chamber 101, creating a plasma. The difference in voltage between the extraction plate 140 and the suppression plate 150 pulls positive ions from the plasma through the extraction slits 141. These ions are accelerated through the suppression slits 151 and the ground slits 161 as well and are directed toward the workpiece disposed on the workpiece holder 170. Due to the positioning and alignment of the slits, the ribbon ion beams 180 are directed toward the workpiece at a non-zero extraction angle and with a small beam angular spread. Further, the workpiece holder 170 is scanned through these angled ribbon ion beams 180 using the motion stage 175. In this way, the workpiece is impacted by two angled ribbon ion beams 180 simultaneously.

The embodiments described above in the present application may have many advantages.

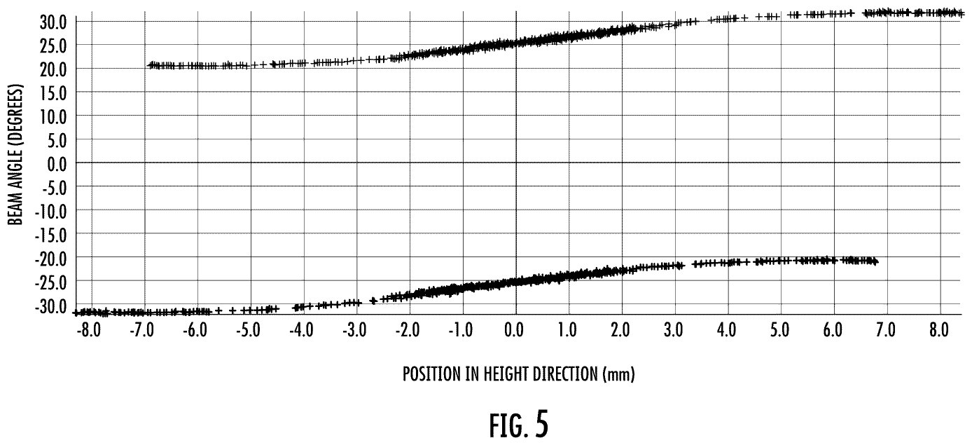

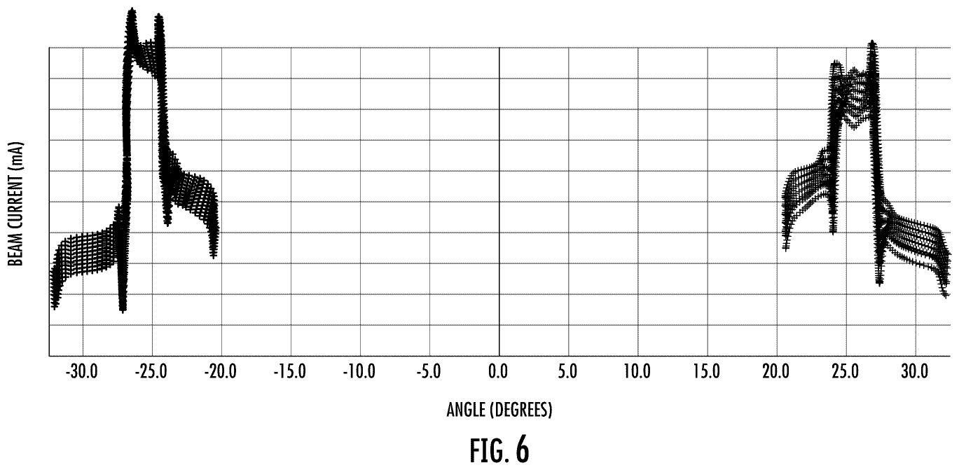

The triode configuration of the extraction optics of the ion source 10 of FIG. 1 allows higher beam current and lower beam angular spread than can otherwise be achieved. FIG. 5 shows the beams emissivity curves at the workpiece plane. For this simulation, the extraction plate 140 was at ground potential, the ground plate 160 and the workpiece holder 170 were at −2.5 kV, and the suppression plate 150 at −10 kV. The workpiece holder 170 was roughly 85 mm away from the ground plate 160. The total extracted ion beam current was 60 mA. The vertical axis represents the incidence angles of the ion beams with respect to the normal on the workpiece plane, while the horizontal axis represents the position of the ion beam in the height direction. Thus, a value of 0 mm indicates the middle of the workpiece. A positive angle value corresponds to the ribbon ion beam pointing up (see FIG. 1), while a negative angle value corresponds to the ribbon ion beam pointing down. Note that the mean angles are about 25° and −25°, respectively, with an angular spread of roughly ±5°. Thus, the ribbon ion beams show a beam divergence of about 1.25° per mm. FIG. 6 shows the ion angular distribution. In this graph, the vertical axis represents beam current, while the horizontal axis represents the incidence angle of the ribbon ion beam with respect to the normal on the workpiece plane at the workpiece location. Note that the current is tightly grouped around 25° and −25°, with a beam angular spread of about ±5°.

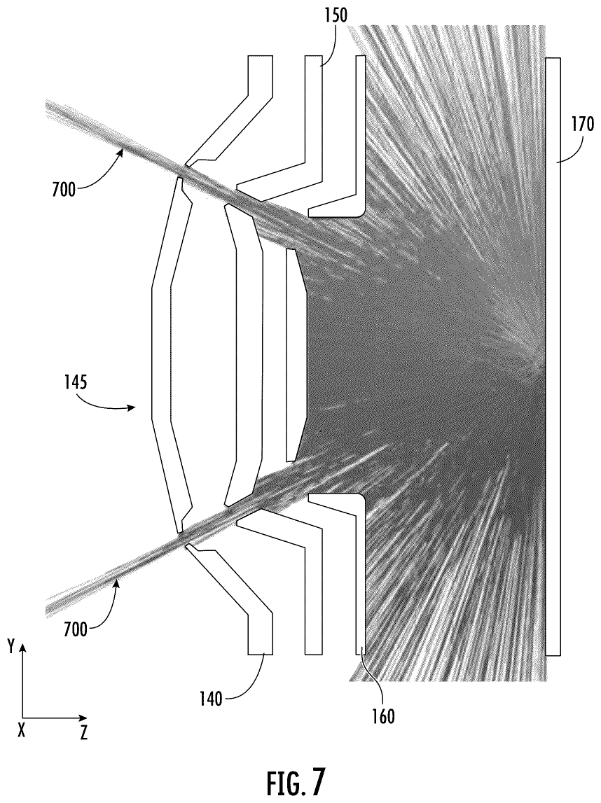

In addition to the improvements in ion beam current and beam angular spread described above, the triode configuration has other benefits. Being biased at negative voltage relative to the workpiece, the suppression plate 150 repels secondary electrons emitted at the workpiece surface by ion beam bombardment. Thus, electrons do not enter the plasma chamber 101 and ion source operation is stable. The triode configuration allows a reduction of the sputtered material entering the ion source 10. In existing systems which do not have these extraction optics, a considerable amount of sputtered material may enter the plasma chamber 101 where it deposits on the chamber walls inclusively of the dielectric window 109. These deposits reduce the RF power coupling to the plasma and consequently cause the plasma characteristics to drift during operation. Therefore, in order to mitigate this detrimental aspect, the plasma chamber 101 is periodically cleaned by running a plasma with a mixture of O₂ and CF₄ gases. This cleaning step consumes time which translates into lower processing throughput. FIG. 7 depicts the distribution of sputtered material 700 using the conditions of ion extraction described above. For this simulation, the workpiece material was silicon and a Lambertian distribution of the sputtered atoms was assumed. Given the small solid angle that the plasma chamber sees the workpiece, a very small amount of sputtered material enters the plasma chamber 101. The result is prolonged operation time between cleanings.

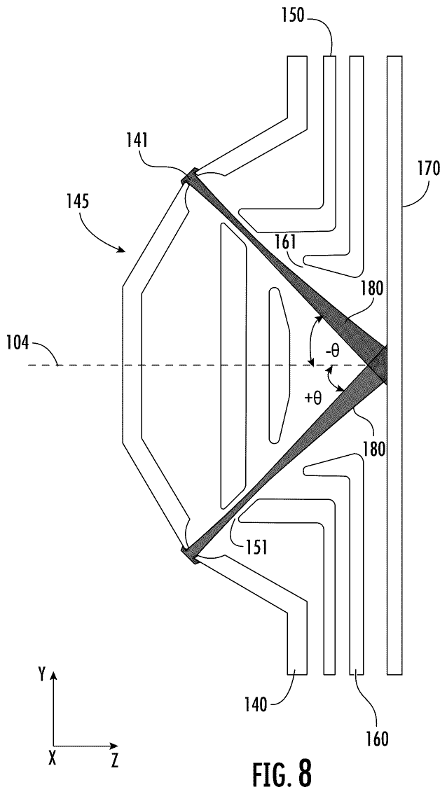

Furthermore, the triode configuration is not limited to the embodiment shown in FIG. 1. FIG. 8 shows a different configuration of the extraction plate 140, the suppression plate 150 and the ground plate 160. The rest of the ion source 10 is not shown, but is the same as that shown in FIG. 1. In this embodiment, the slits in the plates are arranged so as to extract ribbon ion beams 180 having angles of θ° and −θ°, wherein θ is roughly 42°. As explained above, the slits in the three plates are all parallel and centrally aligned. Further, as shown in FIG. 8, in certain embodiments, the suppression plate 150 may be closest to the extraction plate 140 near the suppression slit 151.

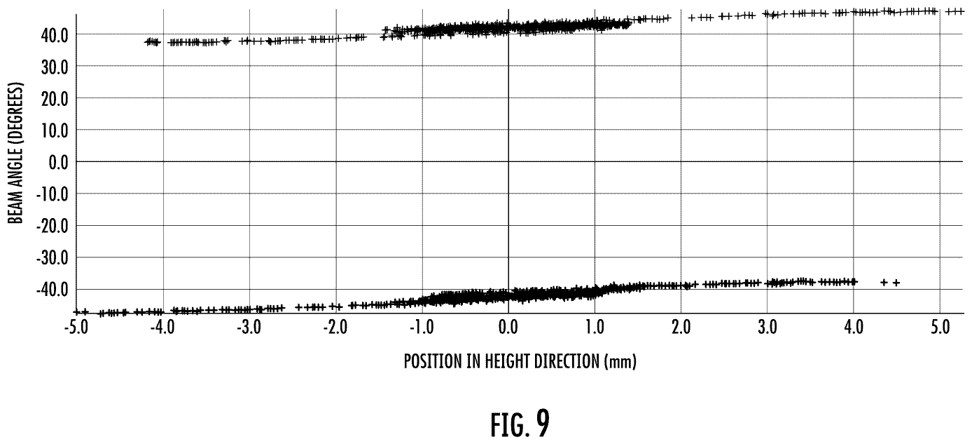

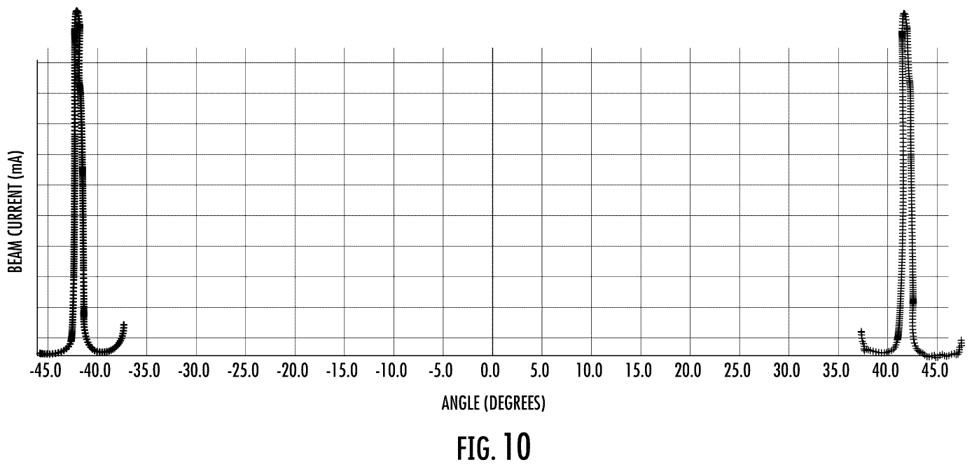

FIG. 9 shows the beam emissivity curves for the triode configuration of FIG. 8. For this simulation, the extraction plate 140 was at ground potential, the ground plate 160 and the workpiece holder 170 were at −2.5 kV, and the suppression plate 150 was biased at −10 kV. The workpiece holder 170 was roughly 47 mm away from the ground plate 160. The total extracted ion beam current was 60 mA. The vertical axis represents the incidence angle of the ribbon ion beams 180 on the workpiece at the workpiece location, while the horizontal axis represents the position of the ribbon ion beams 180 in the height direction. Thus, a value of 0 mm indicates the center of the workpiece, a positive angle value represents the ribbon ion beam propagating in the up direction (see FIG. 8), while a negative angle value represents the ribbon ion beam propagating down. Note that the mean angle is about 42° and −42°, respectively, with an angular spread of roughly ±2.5°. The ion beam has a divergence of about 1° per mm. FIG. 10 shows the ion angular distribution corresponding to the triode configuration of FIG. 8. In this graph, the vertical axis represents beam current, while the horizontal axis represents the incidence angle of the ribbon ion beam on the workpiece surface at the location of the workpiece. Note that the current is tightly grouped around 42° and −42°, with a beam angular spread of about ±1°.

While the disclosure describes extraction angles of 25° and 42°, it is understood that the slits may be arranged to create multiple ion beams having extraction angles between 10° and 75° and −10° and −75°, respectively. Additionally, the angular spread may be ±5° or less for these different extraction angles. Further, while the disclosure described ions beams that are symmetric about center line 104, it is understood that the two ion beams may have a different relationship to each other and to center line 104.

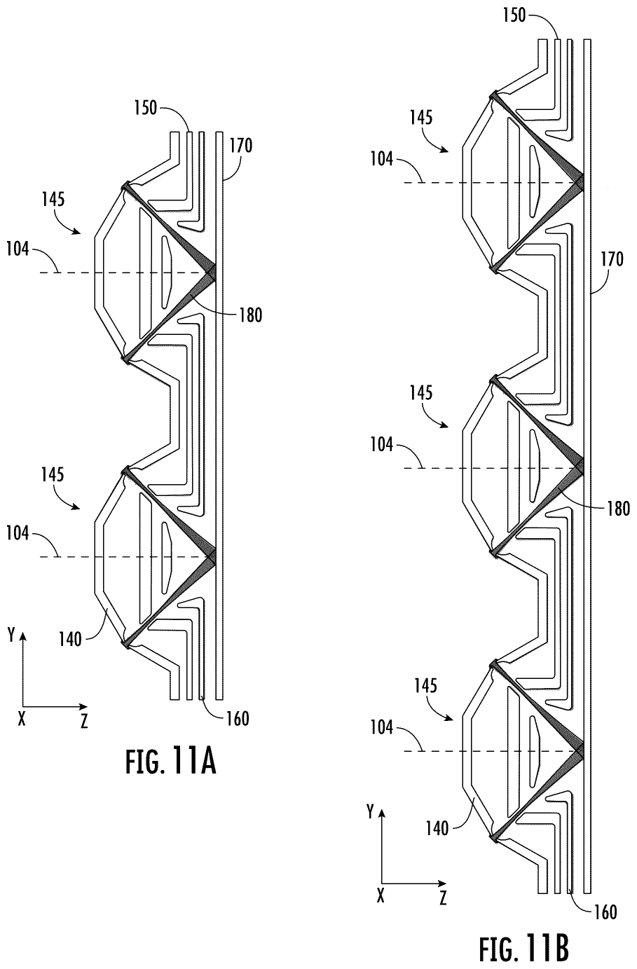

Furthermore, while FIGS. 1 and 8 show an ion source 10 with one triode configuration that produces two ribbon ion beams, other embodiments are also possible. For example, the extracted beam current and consequently, the processing throughput can be increased by increasing the number of beams. As shown in FIG. 11A, two triode configurations can be placed adjacent to one another within the same ion source, thus resulting in twice the extracted ion beam current. Specifically, the concave region 145 described above may be replicated such that the extraction plate 140 has two concave regions 145. The configuration of the suppression plate 150 and the ground plate 160 in the region near each concave region 145 may be as described above. Thus, there are two pairs of ribbon ion beams, each one pair of ribbon ion beams is associated with each concave region 145. Furthermore, if plasma chamber 101 is tall enough in the height direction, then three triode configurations may be placed adjacent to one another, thus resulting in six extracted ion beams as shown in FIG. 11B. Note that while FIGS. 11A-11B show all of the sets of extracted ribbon ion beams having the same incidence angles, the extraction plate 140 may be designed such that ribbon ion beams of different incidence angles are extracted through each triode configuration. Additionally, in certain embodiments, each pair of ribbon ion beams which are extracted through a triode configuration are symmetric with respect to a line normal to the workpiece holder 170.

As demonstrated above, the triode configuration of the ion extraction optics has many benefits. First, the beam angular spread is very narrow, such as only a few degrees, which allows very precise ion beam processing of high aspect ratio semiconductor structures. For example, a trench vertical wall can be pushed without wasting beam in erosion of the hard mask or the bottom of the trench. Second, there is an increase of the extracted ion beam current for the same extraction voltage (ion energy). In some embodiments, the current may be doubled while preserving the angular distribution; if a plasma flood gun and continuous extraction (dc operation) are employed, the extracted current may be quadrupled. Third, since the workpiece holder is not part of the ion extraction optics, variation of z gap length (the distance between the extraction plate 140 and the workpiece holder 170) without affecting beam characteristics is possible. Further, it is possible to reduce the level of sputtered material that enters the ion source and prevent secondary electrons from streaming back into the ion source.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An ion source, comprising:
a plasma housing defining a plasma chamber;
a plasma generator to create a plasma within the plasma chamber; and
triode extraction optics, comprising:
an extraction plate physically coupled to the plasma housing;
a suppression plate; and
a ground plate;
wherein the suppression plate is disposed between the extraction plate and the ground plate and each plate comprises two or more slits to allow for simultaneous extraction of multiple ion beams at different extraction angles.

2. The ion source of claim 1, wherein the extraction plate comprises a concave region such that a center of the concave region in a height direction extends into the plasma chamber more than distal ends of the extraction plate.

3. The ion source of claim 2, wherein the concave region includes two slits on opposite sides of the center of the concave region.

4. The ion source of claim 3, wherein two ion beams extracted through the two slits are symmetric about a line normal to a workpiece and passing through the center of the concave region.

5. The ion source of claim 3, wherein the extraction plate comprises two concave regions, and the suppression plate and the ground plate each have four slits, allowing for simultaneous extraction of four ion beams.

6. The ion source of claim 3, wherein the extraction plate comprises three concave regions, and the suppression plate and the ground plate each have six slits, allowing for simultaneous extraction of six ion beams.

7. The ion source of claim 3, wherein the extraction plate is arc-shaped.

8. The ion source of claim 3, wherein the suppression plate and the ground plate each comprise a concave shape.

9. The ion source of claim 8, wherein the suppression plate is arc-shaped or box shaped.

10. The ion source of claim 8, wherein the ground plate is arc-shaped or box shaped.

11. The ion source of claim 1, wherein a difference in voltage between the extraction plate and the ground plate defines an extraction voltage, and wherein a voltage applied to the suppression plate is more negative than a voltage applied to the ground plate.

12. The ion source of claim 1, wherein a separation between the suppression plate and the extraction plate is smallest at the two or more slits of the suppression plate.

13. A workpiece processing system, comprising:
an ion source, comprising:
a plasma housing defining a plasma chamber;
a plasma generator to create a plasma within the plasma chamber; and
triode extraction optics, comprising:
an extraction plate physically coupled to the plasma housing;
a suppression plate; and
a ground plate;
wherein the suppression plate is disposed between the extraction plate and the ground plate,
wherein the extraction plate comprises one or more concave region, wherein each concave region includes two extraction slits on opposite sides of a center of the concave region in a height direction, and the suppression plate and the ground plate each comprises two or more slits to allow for simultaneous extraction of multiple ion beams at different extraction angles; and
a workpiece holder configured to hold a workpiece to be processed by the multiple ion beams.

14. The workpiece processing system of claim 13, wherein the workpiece holder moves in the height direction relative to the plasma housing.

15. The workpiece processing system of claim 14, wherein a voltage applied to the workpiece holder is a same voltage as a voltage applied to the ground plate such that there is no electrical field between the ground plate and the workpiece holder.

16. The workpiece processing system of claim 13, wherein two ion beams are extracted from the two extraction slits in each concave region, and the two ion beams are directed toward the workpiece holder at extraction angles between 10° and 75° and —10° and −75°, respectively.

17. The workpiece processing system of claim 16, wherein the two ion beams are symmetric about a center line of the concave region in a height direction.

18. The workpiece processing system of claim 13, wherein the extraction plate comprises two concave regions arranged in the height direction, allowing for simultaneous extraction of four ion beams.

19. The workpiece processing system of claim 13, wherein the extraction plate comprises three concave regions arranged in the height direction, allowing for simultaneous extraction of six ion beams.

20. The workpiece processing system of claim 13, wherein an angular spread of each of the multiple ion beams is ±5° or less.
